(19) United States
(12) Patent Application Publication
(10) Pub. No.: US 2015/0327411 A1
(43) Pub. Date: Nov. 12, 2015

(54) DISPLAY PANEL DEVICE WITH MULTIPLE ELECTROSTATIC DISCHARGE RINGS

(71) Applicant: InnoLux Corporation, Miao-Li County (TW)

(72) Inventor: Sheng-Feng HUANG, Miao-Li County (TW)

(21) Appl. No.: 14/676,124

(22) Filed: Apr. 1, 2015

Related U.S. Application Data
(60) Provisional application No. 61/991,254, filed on May 9, 2014.

(30) Foreign Application Priority Data
Jul. 7, 2014 (TW) 103123286

(51) Int. Cl. H05K 9/00

(52) U.S. Cl. CPC H05K 9/0067; H05K 9/0079

(57) ABSTRACT

A display panel device with multiple electrostatic discharge rings includes a substrate, a display circuit, a first electrostatic discharge ring, and a second electrostatic discharge ring. The display circuit is arranged on the substrate and includes a semiconductor layer and a metal layer. The first electrostatic discharge ring is arranged at the same layer with the metal layer on the substrate for surrounding the display circuit. The second electrostatic discharge ring is arranged at the same layer with the semiconductor layer on the substrate for surrounding the first electrostatic discharge ring.

### BACKGROUND OF THE INVENTION

1. Field of the Invention

The present invention relates to a device with multiple electrostatic discharge rings and, more particularly, to a display panel device with multiple electrostatic discharge rings.

2. Description of Related Art

An electrostatic discharge ring is usually arranged in a general display panel for protecting display panel circuit. As shown in FIG. 1, it is a schematic diagram of a prior display panel structure. The display panel 1 includes a display circuit 3 and an electrostatic discharge ring 4. With reference to FIG. 2, it schematically illustrates a part of the prior display panel edge in details, which is denoted by a circle 10 in FIG. 1. The electrostatic discharge ring 4 is disposed between an edge 11 of the display panel 1 and a metal layer 30 of the display circuit 3 for surrounding the display circuit 3 so as to prevent the display circuit and the display panel 1 from being damaged by electrostatic energy. However, when electrostatic energy is huge, it could not stop a damage of electrostatic energy because the electrostatic discharge ring 4 is made of metal material having a low resistance value.

Therefore, it is desirable to provide a display panel device with multiple electrostatic discharge rings for effectively avoiding a damage of the electrostatic energy.

### SUMMARY OF THE INVENTION

The object of the present invention is to provide a display panel device with multiple electrostatic discharge rings, which can effectively avoid a damage of the electrostatic energy so as to provide the effect of electrostatic discharge protection.

To achieve the object, there is provided a display panel device with multiple electrostatic discharge rings, which comprise: a substrate; a display circuit arranged on the substrate, wherein the display circuit includes a semiconductor layer and a metal layer; a first electrostatic discharge ring arranged at a same layer with the metal layer on the substrate and surrounding the display circuit; and a second electrostatic discharge ring arranged at a same layer with the semiconductor layer on the substrate and surrounding the first electrostatic discharge ring.

When the electrostatic energy enters the display panel from an edge thereof, the display panel device with multiple electrostatic discharge rings according to the present invention may absorb most of the electrostatic energy by using the second electrostatic discharge ring with a high resistance value, and then absorb the rest of electrostatic energy by using the first electrostatic discharge ring, so as to achieve the effect of electrostatic discharge protection and further prevent the display panel from damage.

### BRIEF DESCRIPTION OF THE DRAWINGS

FIG. 1 is a schematic diagram of a prior display panel structure;

FIG. 2 schematically illustrates a part of the prior display panel edge in details;

FIG. 3 is a schematic diagram of a display panel structure according to the present invention;

FIG. 4 schematically illustrates a part of the display panel edge in details according to a first embodiment of the present invention;

FIG. 5(A) schematically illustrates a first exemplary cross-sectional view of the display panel edge according to the first embodiment of the present invention;

FIG. 5(B) schematically illustrates a second exemplary cross-sectional view of the display panel edge according to the first embodiment of the present invention;

FIG. 5(C) schematically illustrates a third exemplary cross-sectional view of the display panel edge according to the first embodiment of the present invention;

FIG. 5(D) schematically illustrates a fourth exemplary cross-sectional view of the display panel edge according to the first embodiment of the present invention;

FIG. 6 schematically illustrates a part of the display panel edge in details according to a second embodiment of the present invention;

FIG. 7 schematically illustrates a part of the display panel edge in details according to a third embodiment of the present invention;

FIG. 8 schematically illustrates a part of the display panel edge in details according to a fourth embodiment of the present invention;

FIG. 9(A) schematically illustrates a first exemplary cross-sectional view of the display panel edge according to the fourth embodiment of the present invention;

FIG. 9(B) schematically illustrates a second exemplary cross-sectional view of the display panel edge according to the fourth embodiment of the present invention;

FIG. 9(C) schematically illustrates a third exemplary cross-sectional view of the display panel edge according to the fourth embodiment of the present invention; and

FIG. 9(D) schematically illustrates a fourth exemplary cross-sectional view of the display panel edge according to the fourth embodiment of the present invention.

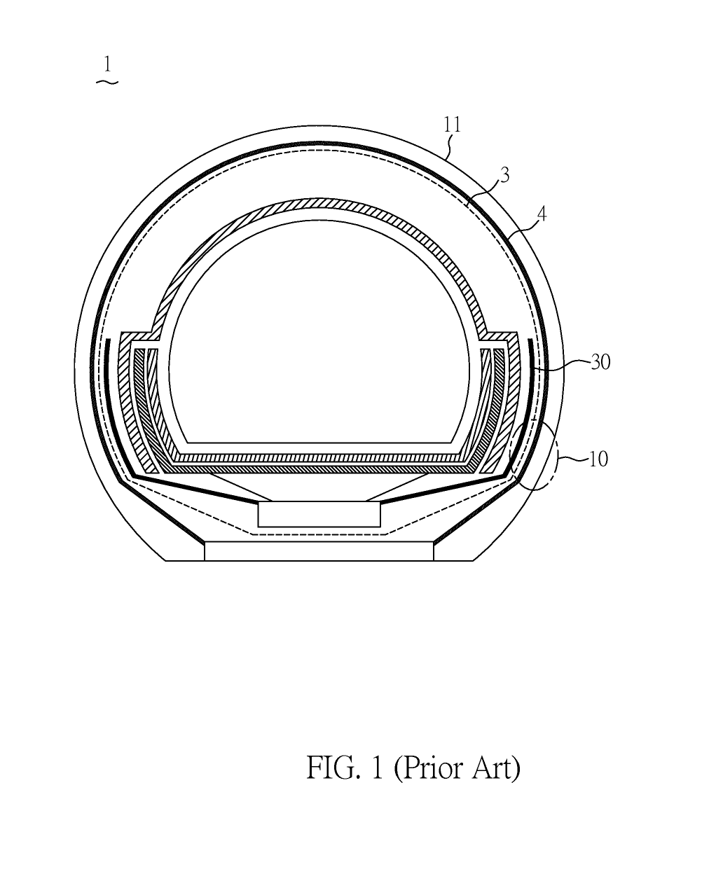

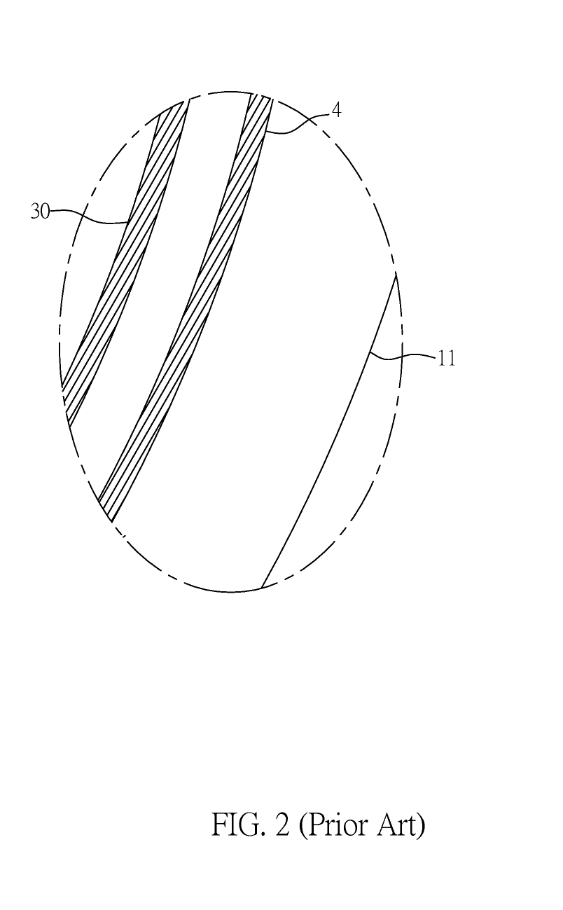

### DETAILED DESCRIPTION OF THE PREFERRED EMBODIMENT

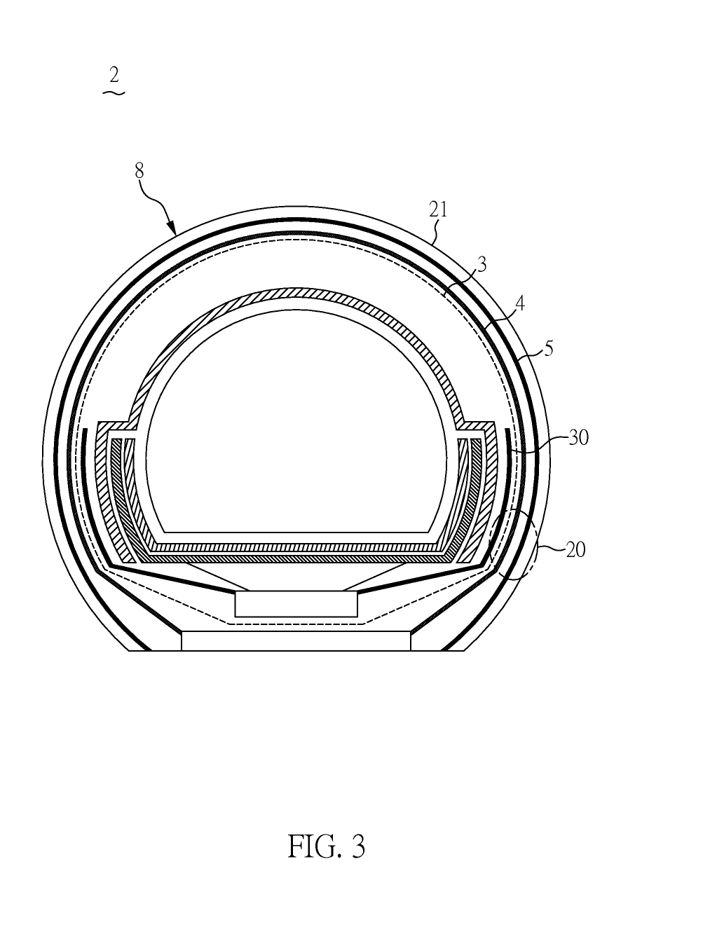

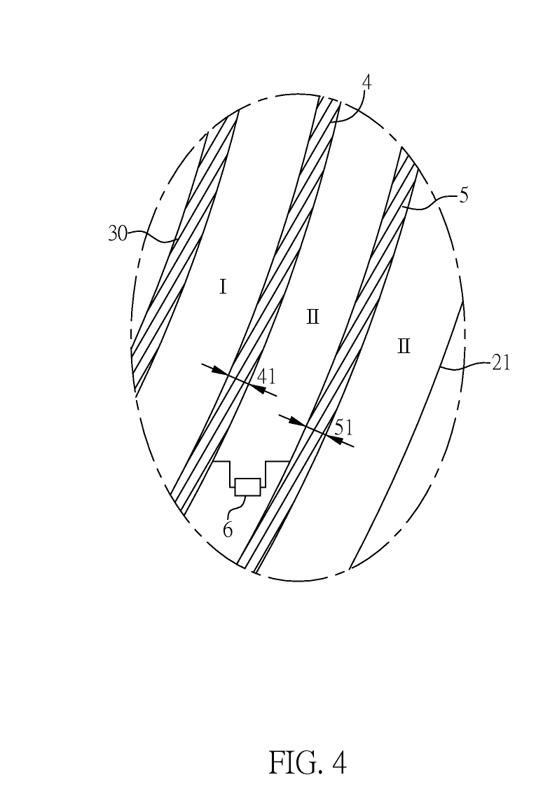

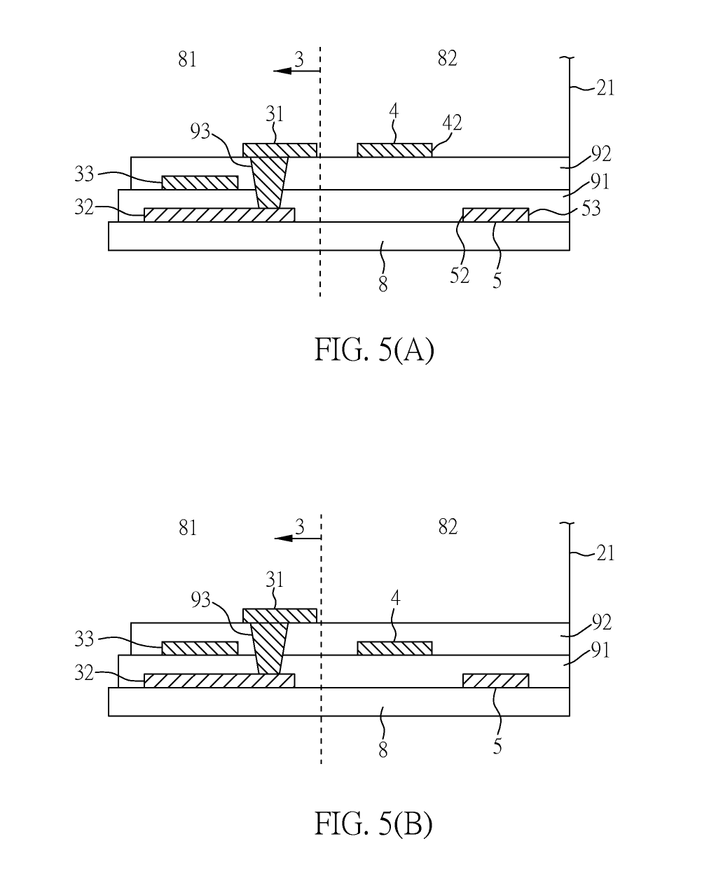

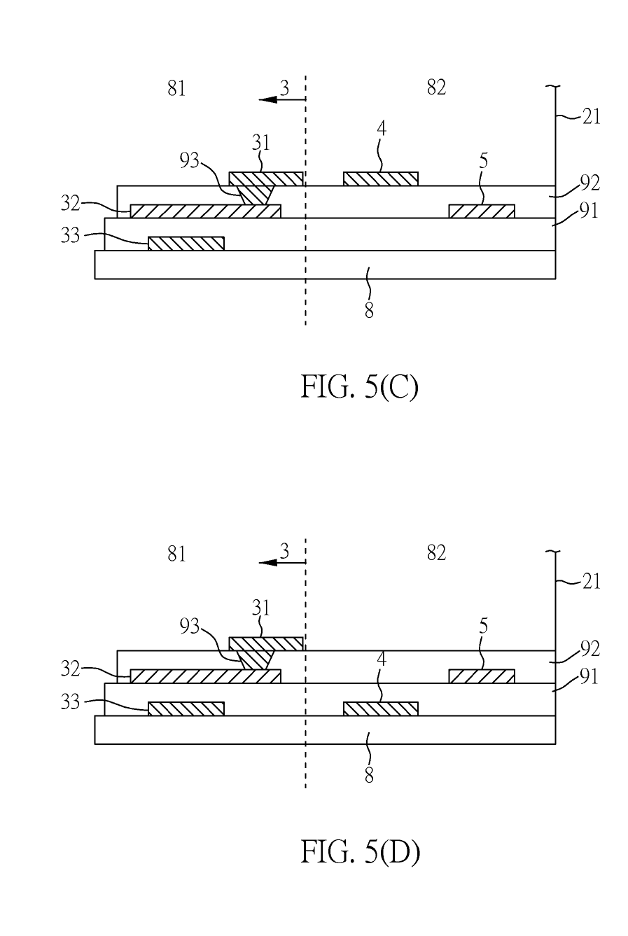

With reference to FIGS. 3, 4, and 5, FIG. 3 is a schematic diagram of a display panel device according to the present invention, FIG. 4 schematically illustrates a part of the display panel edge in details according to a first embodiment of the present invention, and FIG. 5(A) schematically illustrates a first exemplary cross-sectional view of the display panel edge. In this embodiment, the display panel device 2 is a round shaped display panel. As shown in the figures, the display panel device 2 with multiple electrostatic discharge rings comprises: a substrate 8, a display circuit 3, a first electrostatic discharge ring 4, and a second electrostatic discharge ring 5. The display circuit 3, the first electrostatic discharge ring 4, and the second electrostatic discharge ring 5 are arranged on the substrate 8.

As shown in FIG. 3, the display circuit 3 includes a metal layer 30. The first electrostatic discharge ring 4 is arranged at the same layer with the metal layer 30 on the substrate 8 and surrounds the display circuit 3. The second electrostatic discharge ring 5 surrounds the first electrostatic discharge ring 4. FIG. 4 is an enlarged diagram of the circle 20 in FIG. 3. As shown, there is a first space I between the first electrostatic discharge ring 4 and the metal layer 30 of the display circuit 3, and there is a second space II between the first electrostatic discharge ring 4 and an edge 21 of the substrate 8. The second electrostatic discharge ring 5 is disposed in the second space II . Further, the width 51 of the second electrostatic discharge ring 5 is larger than the width 41 of the first electrostatic discharge ring 4. In another embodiment, the first electrostatic discharge ring 4 and the second electrostatic discharge ring 5 are coupled to a connection module 6 and grounded (not shown) for releasing electrostatic energy.

Besides, the first electrostatic discharge ring 4 is made of metal material with a first resistance value, and the second electrostatic discharge ring 5 is made of non-metal material with a second resistance value, wherein the first resistance value is different from the second resistance value. Preferably, the second resistance value is larger than the first resistance value, and a ratio of the second resistance value to the first resistance value is 5 to 5×10¹⁰. In another embodiment, the second electrostatic discharge ring 5 is made of semiconductor material. Because the second electrostatic discharge ring 5 has a high resistance value, most of the electrostatic energy from outside can be depleted effectively, and then the rest of the electrostatic energy is depleted by the first electrostatic discharge ring 4 with low resistance value and is finally grounded to release the electrostatic energy thereby avoiding the display circuit 3 from being damaged by the electrostatic energy so as to protect the display panel device 2.

As shown in FIG. 5(A), the substrate 8 is divided into a display region 81 and a non-display region 82, and the non-display region 82 surrounds the display region 81. The display circuit 3 is disposed at the display region 81, and the first electrostatic discharge ring 4 and the second electrostatic discharge ring 5 are disposed at the non-display region 82. The first electrostatic discharge ring 4 and the second electrostatic discharge ring 5 are disposed at different layers, and there are a first insulating layer 91 and a second insulating layer 92 disposed between the first electrostatic discharge ring 4 and the second electrostatic discharge ring 5. The first electrostatic discharge ring 4 has a first side 42 adjacent to the second electrostatic discharge ring 5. The second electrostatic discharge ring 5 has a second side 52 and a third side 53 arranged along a direction from the display region 81 to the non-display region 82. The second side 52 is adjacent to the first electrostatic discharge ring 4, and the third side 53 is adjacent to an edge 21 of the substrate 8 and far away from the first electrostatic discharge ring 4. The width 51 of the second electrostatic discharge ring 5 is smaller than or equal to the distance between the first side 42 and the edge 21 of the substrate 8.

The display circuit 3 further includes a semiconductor layer 32. The metal layer 30 of the display circuit 3 includes a first metal layer 31 and a second metal layer 33, wherein the first metal layer 31 is a data line and the second metal layer 33 is a gate line. The first metal layer 31 is electrically coupled to the semiconductor layer 32 via a contact hole 93. The second electrostatic discharge ring 5 and the semiconductor layer 32 of the display circuit 3 are disposed at the same layer on the substrate 8, wherein the material of the semiconductor layer 32 is selected from the group consisting of poly-silicon, non-poly-silicon or metal oxide. The first electrostatic discharge ring 4 and the first metal layer 31 of the display circuit 3 are disposed at the same layer on the substrate 8.

FIG. 5(B) schematically illustrates a second exemplary cross-sectional view of the display panel edge according to the first embodiment of the present invention. FIG. 5(B) is similar to FIG. 5(A) except that the first electrostatic discharge ring 4 and the second metal layer 33 of the display circuit 3 are disposed at the same layer on the substrate 8, and the first insulating layer 91 is disposed between the first electrostatic discharge ring 4 and the second electrostatic discharge ring 5.

FIG. 5(C) schematically illustrates a third exemplary cross-sectional view of the display panel edge according to the first embodiment of the present invention. FIG. 5(C) is similar to FIG. 5(A) except that the semiconductor layer 32 of the display circuit 3 is disposed between the first metal layer 31 and the second metal layer 33 of the display circuit 3, the second electrostatic discharge ring 5 and the semiconductor layer 32 of the display circuit 3 are disposed at the same layer on the substrate 8, and the second insulating layer 92 is disposed between the first electrostatic discharge ring 4 and the second electrostatic discharge ring 5.

FIG. 5(D) schematically illustrates a fourth exemplary cross-sectional view of the display panel edge according to the first embodiment of the present invention. FIG. 5(D) is similar to FIG. 5(A) except that the semiconductor layer 32 of the display circuit 3 is disposed between the first metal layer 31 and the second metal layer 33 of the display circuit 3, the second electrostatic discharge ring 5 and the semiconductor layer 32 of the display circuit 3 are disposed at the same layer on the substrate 8, the first electrostatic discharge ring 4 and the second metal layer 33 of the display circuit 3 are disposed at the same layer on the substrate 8, and the first insulating layer 91 is disposed between the first electrostatic discharge ring 4 and the second electrostatic discharge ring 5.

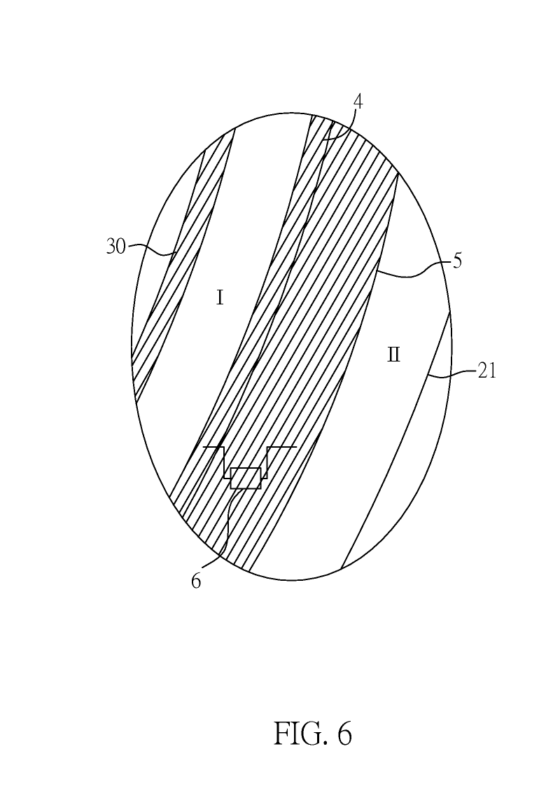

With reference to FIG. 6, it schematically illustrates a part of the display panel edge in details according to a second embodiment of the present invention. The structure of this embodiment is similar to that of the first embodiment except that the second side 52 of the second electrostatic discharge ring 5 is aligned with the first side 42 of the first electrostatic discharge ring 4.

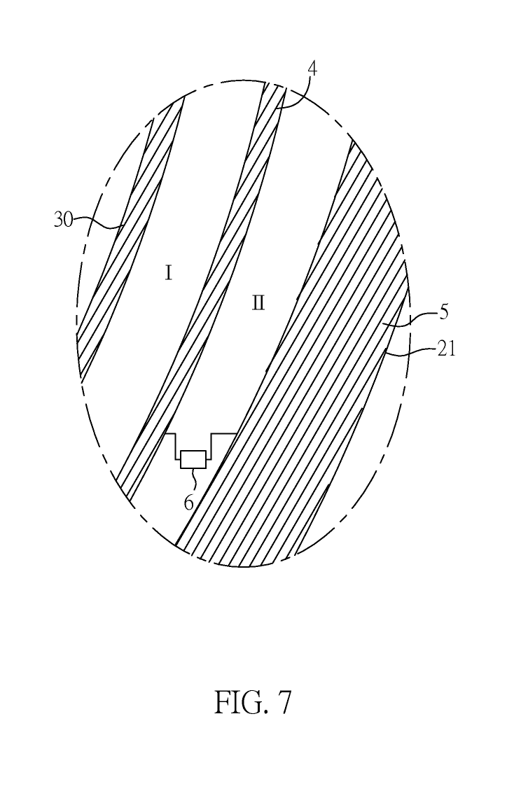

With reference to FIG. 7, it schematically illustrates a part of the display panel edge in details according to a third embodiment of the present invention. The structure of this embodiment is similar to that of the first embodiment except that the third side 53 of the second electrostatic discharge ring 5 is aligned with the edge 21 of the substrate 8.

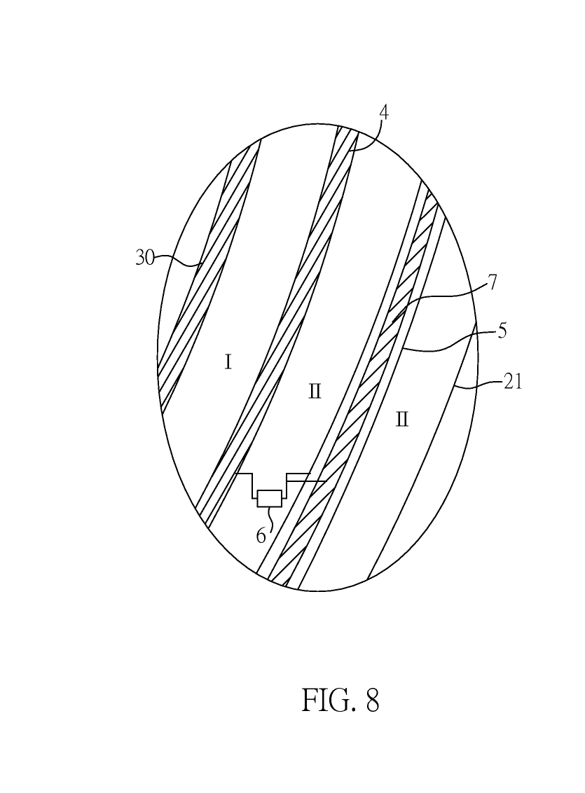

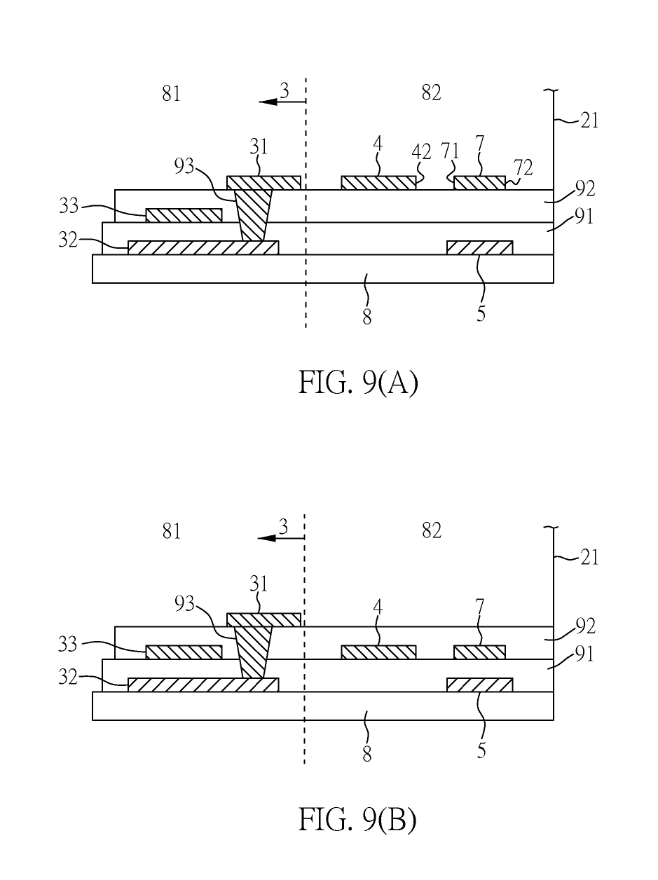

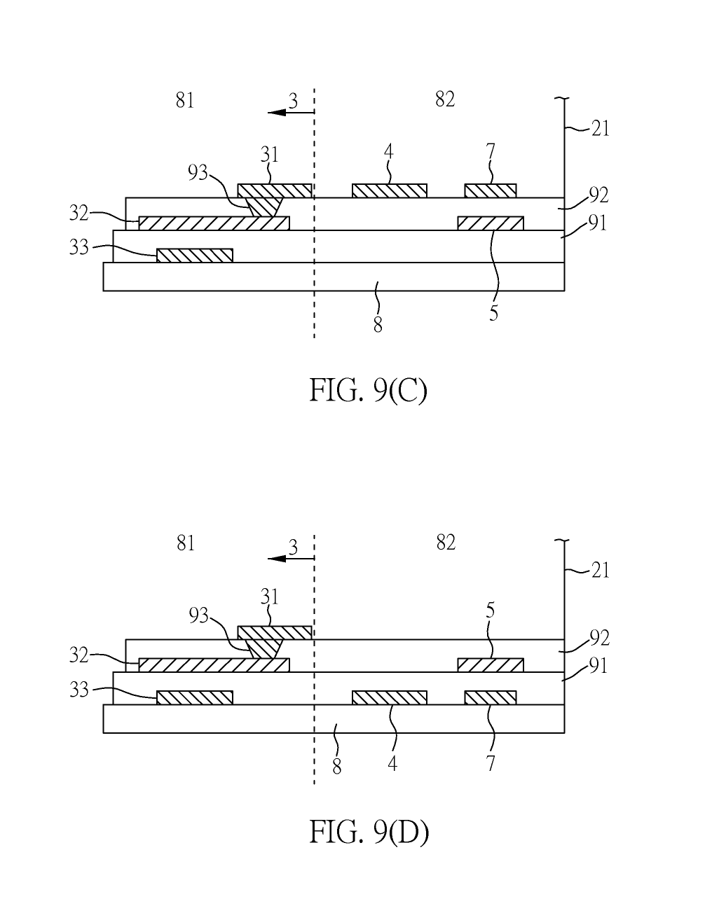

With reference to FIGS. 8 and 9(A), FIG. 8 schematically illustrates a part of the display panel edge in details according to a fourth embodiment of the present invention, and FIG. 9(A) schematically illustrates a first exemplary cross-sectional view of the display panel edge according to the fourth embodiment of the present invention. The structure of this embodiment is similar to that of the first embodiment except that the display panel device 2 with multiple electrostatic discharge rings according to the present invention further comprises a third electrostatic discharge ring 7 arranged at the same layer with the first metal layer 31 on the substrate 8 and surrounding the first electrostatic discharge ring 4. The third electrostatic discharge ring 7 is made of metal material with a third resistance value different from the first and second resistance values. The third electrostatic discharge ring 7 overlaps a portion of the second electrostatic discharge ring 5, and there are the first insulating layer 91 and the second insulating layer 92 disposed between the first electrostatic discharge ring 4 and the second electrostatic discharge ring 5 or between the third electrostatic discharge ring 7 and the second electrostatic discharge ring 5. The third electrostatic discharge ring 7 has a fourth side 71 and a fifth side 72 arranged along a direction from the display region 81 to the non-display region 82, and the fourth side 71 is adjacent to the first electrostatic discharge ring 4. In an embodiment, similar to the second electrostatic discharge ring 5 in FIG. 6, the fourth side 71 of the third electrostatic discharge ring 7 is aligned with the first side 42 of the first electrostatic discharge ring 4. In other embodiment, similar to the second electrostatic discharge ring 5 in FIG. 7, the fifth side 72 of the third electrostatic discharge ring 7 is aligned with the edge 21 of the substrate 8.

FIG. 9(B) schematically illustrates a second exemplary cross-sectional view of the display panel edge according to the fourth embodiment of the present invention. FIG. 9(B) is similar to FIG. 9(A) except that the first electrostatic discharge ring 4, the third electrostatic discharge ring 7, and the second metal layer 33 of the display circuit 3 are disposed at the same layer on the substrate 8, and the first insulating layer 91 is disposed between the first electrostatic discharge ring 4 and the second electrostatic discharge ring 5 or between the third electrostatic discharge ring 7 and the second electrostatic discharge ring 5.

FIG. 9(C) schematically illustrates a third exemplary cross-sectional view of the display panel edge according to the fourth embodiment of the present invention. FIG. 9(C) is similar to FIG. 9(A) except that the semiconductor layer 32 of the display circuit 3 is disposed between the first metal layer 31 and the second metal layer 33 of the display circuit 3, the second electrostatic discharge ring 5 and the semiconductor layer 32 of the display circuit 3 are disposed at the same layer on the substrate 8, and the second insulating layer 92 is disposed between the first electrostatic discharge ring 4 and the second electrostatic discharge ring 5 or between the third electrostatic discharge ring 7 and the second electrostatic discharge ring 5.

FIG. 9(D) schematically illustrates a fourth exemplary cross-sectional view of the display panel edge according to the fourth embodiment of the present invention. FIG. 9(D) is similar to FIG. 9(A) except that the semiconductor layer 32 of the display circuit 3 is disposed between the first metal layer 31 of the display circuit 3 and the second metal layer 33 of the display circuit 3, the second electrostatic discharge ring 5 and the semiconductor layer 32 of the display circuit 3 are disposed at the same layer on the substrate 8, the first electrostatic discharge ring 4, the third electrostatic discharge ring 7, and the second metal layer 33 of the display circuit 3 are disposed at the same layer on the substrate 8, and the first insulating layer 91 is disposed between the first electrostatic discharge ring 4 and the second electrostatic discharge ring 5 or the third electrostatic discharge ring 7 and the second electrostatic discharge ring 5.

In view of the foregoing, it is known that, in the present invention, multiple electrostatic discharge rings are arranged on the display panel and the outer electrostatic discharge ring has a high resistance value in comparison with the inner electrostatic discharge ring, so that the outer electrostatic discharge ring can deplete most of the electrostatic energy from outside and then the inner electrostatic discharge ring depletes the rest of the electrostatic energy so as to prevent the display circuit and the display panel from being damaged by the electrostatic energy.

Although the present invention has been explained in relation to its preferred embodiment, it is to be understood that many other possible modifications and variations can be made without departing from the spirit and scope of the invention as hereinafter claimed.

What is claimed is:

1. A display panel device with multiple electrostatic discharge rings, comprising:
a substrate;
a display circuit arranged on the substrate, wherein the display circuit includes a semiconductor layer and a metal layer;
a first electrostatic discharge ring arranged at a same layer with the metal layer on the substrate and surrounding the display circuit; and
a second electrostatic discharge ring arranged at a same layer with the semiconductor layer on the substrate and surrounding the first electrostatic discharge ring.

2. The display panel device as claimed in claim 1, wherein the first electrostatic discharge ring is electrically coupled to the second electrostatic discharge ring and is grounded.

3. The display panel device as claimed in claim 1, wherein the first electrostatic discharge ring has a first resistance value, the second electrostatic discharge ring has a second resistance value, and the first resistance value is different from the second resistance value.

4. The display panel device as claimed in claim 3, wherein the second resistance value is larger than the first resistance value.

5. The display panel device as claimed in claim 4, wherein a ratio of the second resistance value to the first resistance value is 5 to 5×10¹⁰.

6. The display panel device as claimed in claim 1, wherein a width of the second electrostatic discharge ring is larger than that of the first electrostatic discharge ring.

7. The display panel device as claimed in claim 1, wherein the first electrostatic discharge ring is made of metal material.

8. The display panel device as claimed in claim 1, wherein the second electrostatic discharge ring is made of non-metal material.

9. The display panel device as claimed in claim 8, wherein the second electrostatic discharge ring is made of semiconductor material.

10. The display panel device as claimed in claim 1,
wherein the substrate is divided into a display region and a non-display region, and the non-display region surrounds the display region,
wherein the display circuit is disposed at the display region, and the first electrostatic discharge ring and the second electrostatic discharge ring are disposed at the non-display region.

11. The display panel device as claimed in claim 10,
wherein the first electrostatic discharge ring and the second electrostatic discharge ring are disposed at different layers,
wherein the first electrostatic discharge ring has a first side adjacent to the second electrostatic discharge ring,
wherein the second electrostatic discharge ring has a second side and a third side arranged along a direction from the display region to the non-display region, the second side is adjacent to the first electrostatic discharge ring, and the third side is adjacent to an edge of the substrate and far away from the first electrostatic discharge ring.

12. The display panel device as claimed in claim 11, wherein the second side of the second electrostatic discharge ring is aligned with the first side of the first electrostatic discharge ring.

13. The display panel device as claimed in claim 11, wherein the third side of the second electrostatic discharge ring is aligned with the edge of the substrate.

14. The display panel device as claimed in claim 11, wherein a width of the second electrostatic discharge ring is smaller than or equal to a distance between the first side and the edge of the substrate.

15. The display panel device as claimed in claim 1, further comprising a third electrostatic discharge ring arranged at a same layer with the metal layer on the substrate and surrounding the first electrostatic discharge ring.

16. The display panel device as claimed in claim 15, wherein the third electrostatic discharge ring has a third resistance value different from the first and second resistance values, and the third electrostatic discharge ring overlaps a portion of the second electrostatic discharge ring.

17. The display panel device as claimed in claim 15, wherein the third electrostatic discharge ring is made of metal material.

18. The display panel device as claimed in claim 15, wherein the third electrostatic discharge ring has a fourth side and a fifth side arranged along a direction from the display region to the non-display region, and the fourth side is aligned with the first electrostatic discharge ring.

19. The display panel device as claimed in claim 18, wherein the fourth side of the third electrostatic discharge ring is aligned with the first side of the first electrostatic discharge ring.

20. The display panel device as claimed in claim 18, wherein the fifth side of the third electrostatic discharge ring is aligned with the edge of the substrate.
